(19) United States
(12) Patent Application Publication
(10) Pub. No.: US 2016/0068747 A1
(43) Pub. Date: Mar. 10, 2016

(54) PHOSPHOR, METHOD FOR PRODUCING THE SAME, AND LIGHT-EMITTING DEVICE USING THE SAME

(71) Applicant: KABUSHIKI KAISHA TOSHIBA, Minato-ku (JP)

(72) Inventors: Aoi OKADA, Kawasaki (JP); Masahiro KATO, Naka (JP); Yasushi HATTORI, Kawasaki (JP)

(73) Assignee: KABUSHIKI KAISHA TOSHIBA, Minato-ku (JP)

(21) Appl. No.: 14/842,093

(22) Filed: Sep. 1, 2015

(30) Foreign Application Priority Data
Sep. 5, 2014 (JP) 2014-181531

(51) Int. Cl. C09K 11/77; H01L 33/50

(52) U.S. Cl. CPC C09K 11/7721; H01L 33/502; H01L 33/504

(57) ABSTRACT

The present embodiment is to provide a blue light-emitting phosphor that enables a white light-emitting device with high color rendering properties to be formed. The phosphor exhibits a luminescence peak in a wavelength range of 430 to 490 nm when excited with light having a luminescence peak within a wavelength range of 250 to 430 nm, wherein the phosphor includes a composition represented by the following formula (1): ((SrₚM₁₋ₚ)₁₋ₓCeₓ)_{3-y}Si_{13-z}Al_{3+z}O₂₊ᵤN_{21-w} (1) (wherein M is at least one of alkaline earth metals; and 0≦p≦1, 0<x≦1, −0.1≦y≦0.6, −3.0≦z≦0.4, −1.5<u≦−0.3, and −3.0<u−w≦1.0 are satisfied).

### CROSS-REFERENCE TO RELATED APPLICATIONS

This application is based upon and claims the benefit of priority from the prior Japanese Patent Application No. 2014-181531, filed on Sep. 5, 2014, the entire contents of which are incorporated herein by reference.

### BACKGROUND OF THE INVENTION

1. Field of the Invention

An embodiment of the present invention relates to a phosphor, a method for producing the phosphor, and a light-emitting device using the phosphor.

2. Description of the Related Art

Research on light-emitting devices using LEDs in recent years has been pursued. Particularly in white LED light-emitting devices, high color rendering properties have been demanded.

### BRIEF DESCRIPTION OF THE DRAWINGS

FIG. 1 is a schematic view illustrating the configuration of a light-emitting device according to an embodiment;

FIGS. 2A and 2B are schematic views illustrating the configuration of a light-emitting device according to another embodiment;

FIG. 3 is the emission spectrum of a phosphor according to Example 2;

FIG. 4 is the emission spectrum of a phosphor according to Example 3;

FIG. 5 is the XRD profile of the phosphor according to Example 1;

FIG. 6 is the XRD profile of the phosphor according to Example 2;

FIG. 7 is the XRD profile of the phosphor according to Example 3;

FIG. 8 is the XRD profile of a phosphor according to Example 4;

FIG. 9 is the XRD profile of a phosphor according to Example 5;

FIG. 10 is the XRD profile of a phosphor according to Example 6;

FIG. 11 is the XRD profile of a phosphor according to Example 7;

FIG. 12 is the XRD profile of a phosphor according to Example 8; and

FIG. 13 shows the emission spectra of light emitted from a light-emitting device.

### DETAILED DESCRIPTION OF THE PREFERRED EMBODIMENTS

Embodiments will now be explained with reference to the accompanying drawings.

A phosphor according to an embodiment exhibits a luminescence peak in a wavelength range of 430 to 490 nm when excited with light having a luminescence peak within a wavelength range of 250 to 430 nm,

wherein the phosphor represented by the following formula (1):

((SrₚM₁₋ₚ)₁₋ₓCeₓ)_{3-y}Si_{13-z}Al_{3+z}O₂₊ᵤN_{21-w} (1)

(wherein M is at least one of alkaline earth metals; and

0≦p≦1,

0<x≦1,

−0.1≦y≦0.6,

−3.0≦z≦0.4,

−1.5<u≦−0.3, and

−3.0<u−w≦1.0

are satisfied).

A phosphor according to another embodiment comprises a composition represented by the following formula (1):

((SrₚM₁₋ₚ)₁₋ₓCeₓ)_{3-y}Si_{13-z}Al_{3+z}O₂₊ᵤN_{21-w} (1)

(wherein M is at least one of alkaline earth metals; and

0≦p≦1,

0<x≦1,

−0.1≦y≦0.6,

−3.0≦z≦0.4,

−1.5<u≦−0.3, and

−3.0<u−w≦1.0

are satisfied)

wherein the phosphor is obtained by burning, at a temperature of 1500 to 2000° C. under a pressure that is not less than atmospheric pressure, a raw material mixture obtained by mixing a Sr-containing raw material selected from nitrides, silicides, carbides, carbonates, hydroxides, and oxides of Sr, a M-containing raw material selected from nitrides, silicides, carbides, carbonates, hydroxides, and oxides of M, an Al-containing raw material selected from nitrides, oxides, and carbides of Al, a Si-containing raw material selected from nitrides, oxides, and carbides of Si, and a Ce-containing raw material selected from chlorides, oxides, nitrides, and carbonates of Ce; and

the phosphor exhibiting a luminescence peak in a wavelength range of 430 to 490 nm when excited with light having a luminescence peak in a wavelength range of 250 to 430 nm.

A light-emitting device according to an embodiment comprises:

a light-emitting element which emits light having a luminescence peak in a wavelength range of 250 to 430 nm;

the first phosphor as defined above; and

a second phosphor which emits light having a peak in a wavelength range of 500 to 600 nm when excited with irradiation light from the light-emitting element.

A light-emitting device according to another embodiment comprises:

a light-emitting element which emits light having a luminescence peak in a wavelength range of 250 to 430 nm;

the first phosphor as defined above;

a second phosphor which emits light having a peak in a wavelength range of 500 to 600 nm when excited with light from the light-emitting element; and

a third phosphor which emits light having a peak in a wavelength range of 600 to 660 nm when excited with light from the light-emitting element.

A method for producing a phosphor according to an embodiment is a method for producing the phosphor, comprising:

a mixing step for obtaining a mixture by mixing a Sr-containing raw material selected from nitrides, silicides, carbides, carbonates, hydroxides, and oxides of Sr, a M-containing raw material selected from nitrides, silicides, carbides, carbonates, hydroxides, and oxides of M, an Al-containing raw material selected from nitrides, oxides, and carbides of Al, a Si-containing raw material selected from nitrides, oxides, and carbides of Si, and a Ce-containing raw material selected from chlorides, oxides, nitrides, and carbonate of Ce; and

a step for burning the mixture at a temperature of 1500 to 2000° C. under a pressure that is not less than atmospheric pressure.

Embodiments will be specifically described below.

### [Blue Light-Emitting Phosphor]

A phosphor according to an embodiment is a phosphor that can emit light in the blue region because the phosphor exhibits a luminescence peak in a wavelength range of 430 to 490 nm, preferably 440 to 460 nm when excited with light having a luminescence peak in a wavelength range of 250 to 430 nm. Therefore, hereinafter, the phosphor according to the present embodiment is referred to as a blue light-emitting phosphor. One feature of the phosphor according to the present embodiment is the ability to emit blue light even when excitation light emitted from a light-emitting element is in the ultraviolet region. Such a phosphor comprises a host material having a crystal structure that is substantially identical to the crystal structure of Sr₃Si₁₃Al₃O₂N₂₁, and the host material is activated with Ce. The composition of the blue light-emitting phosphor according to the present embodiment is represented by the following formula (1):

((SrₚM₁₋ₚ)₁₋ₓCeₓ)_{3-y}Si_{13-z}Al_{3+z}O₂₊ᵤN_{21-w} (1)

wherein M is at least one of alkaline earth metals; and

0≦p≦1,

0<x≦1,

−0.1≦y≦0.6,

−3.0≦z≦0.4,

−1.5<u≦−0.3, and

−3.0<u−w≦1.0

are satisfied.

As shown in the formula (1) described above, some of metal elements forming a host crystal are substituted by a luminescence center element Ce. M is at least one of the alkaline earth metals, and is preferably at least one selected from Ba, Ca, and Mg. There may be a case in which p of 1 is desirable for optimizing the luminescence properties of the phosphor. However, even in such a case, there is a case in which metals other than Sr and Ce are contained as unavoidable impurities. In general, in such a case, the effects of the present embodiment are sufficiently exhibited.

A case in which Ce is 0.1 mol % or more of the total of Sr, M, and Ce can result in sufficient luminous efficiency. It is unnecessary to contain Sr and M (x=1); however, when x is less than 0.5, reduction in luminous efficiency (concentration quenching) can be suppressed as much as possible. Accordingly, x is preferably 0.001 or more and 0.5 or less. The containing of the luminescence center element Ce allows the phosphor according to the present embodiment to emit light in the blue region, i.e., to emit light having a peak in a wavelength range of 430 to 490 nm when excited with light having a peak in a wavelength range of 250 to 430 nm. Desired properties are not impaired even when some of Ce is substituted by another metal element like unavoidable impurities. Examples of such unavoidable impurities include Tb, Eu, Mn, and the like. Specifically, the percentage of the unavoidable impurities to the total of Ce and the unavoidable impurities is preferably 15 mol % or less, more preferably 10 mol % or less.

When y is 0.6 or more, the number of crystal defects may be increased. In contrast, when y is less than −0.1, luminescence properties may be deteriorated because an excessive alkaline earth metal precipitates as a heterogenous phase. It is preferable that y is −0.05≦y≦0.4.

When z is less than −3.0 or more than 0.4, excessive Si or excessive Al may precipitate as a heterogenous phase. In general, −3.0≦z≦0.4 is satisfied. It is preferable to satisfy −1.5≦z≦0.2.

When u is −1.5 or less, the number of crystal defects may be increased. It is preferable that u is −1.2≦u≦0.

When (u−w) is less than −3.0 or more than 1.0, it may be impossible to maintain a crystal structure specified in the present embodiment. In some cases, a heterogenous phase is generated to prevent the effects of the present embodiment from being exhibited. It is preferable that u is −2.0≦u−w≦0.5.

The phosphor according to the embodiment comprises Al and Si. Al and Si may be substituted by similar elements as far as the effects of the present embodiment are not impaired. Specifically, some of Si may be substituted by Ge, Sn, Ti, Zr, Hf, and the like, and some of Al may be substituted by Ga, In, Sc, Y, La, Gd, Lu, and the like. These elements are preferably 10 mol % or less of the total of Si, Al, and the similar elements.

The phosphor according to the present embodiment includes all of the preferred conditions mentioned above and is therefore capable of emitting blue light with a high degree of efficiency when excited with light having a luminescence peak in a wavelength range of 250 to 430 nm.

It may be considered that the blue light-emitting phosphor according to the present embodiment is based on a Sr₃Si₁₃Al₃O₂N₂₁ crystal, in which Si and Al are replaced with each other, or O and N are replaced with each other, and another metal element such as Ce forms a solid solution. In the present embodiment, such a crystal is referred to as a Sr₃Si₁₃Al₃O₂N₂₁-based crystal. Such replacement or the like may result in slight change of a crystal structure but rarely results in change of an atom position to such a large extent that a chemical bond between skeleton atoms is cleaved. The atom position is determined by the crystal structure, the site occupied by the atom, and its coordinate.

The effects of the present embodiment can be exerted as far as the basic crystal structure of the blue light-emitting phosphor according to the present embodiment is not changed. The phosphor according to the present embodiment may differ from Sr₃Si₁₃Al₃O₂N₂₁ in lattice constants and in the chemical bond lengths of M-N and M-O (distances between near neighbor atoms). A case in which the differences between the corresponding chemical bond lengths are within ±15% of the lattice constants of a structure possessed by a crystal of Sr₃Si₁₃Al₃O₂N₂₁ and of chemical bond lengths (Sr—N and Sr—O) in Sr₃Si₁₃Al₃O₂N₂₁ is defined as an unchanged crystal structure. The lattice constants can be determined by X-ray diffraction or neutron beam diffraction, and the chemical bond lengths (atomic distances) of M-N and M-O can be calculated from atomic coordinates.

A Sr₃Si₁₃Al₃O₂N₂₁ crystal belongs to a monoclinic system, particularly to an orthorhombic system. The lattice constants are a=14.8 Å, b=7.5 Å, and c=9.0 Å.

It is essential for the blue light-emitting phosphor according to the present embodiment to have such a crystal structure. When the chemical bond lengths are changed beyond the ranges, the chemical bonds may be cleaved to form another crystal structure, so that the effects according to the present embodiment may be inhibited.

The blue light-emitting phosphor according to the present embodiment is based on an inorganic compound having a crystal structure that is substantially identical to the crystal structure of Sr₃Si₁₃Al₃O₂N₂₁, in which some of elements Sr forming the compound are substituted by luminescence center ions Ce, and the composition of each element is specified into a predetermined limit. In this case, a preferred property of high quantum efficiency is exhibited.

Whether the structures of the blue light-emitting phosphor according to the present embodiment and a Sr₃Si₁₃Al₃O₂N₂₁ crystal are identical or not can be determined by XRD or neutron diffraction. The phosphor according to the present embodiment has a peak at a specific diffraction angle (2θ) in X-ray diffraction pattern by the Bragg-Brendano method using Cu-Kα line. The phosphor obtained in the present embodiment simultaneously exhibits diffraction peaks preferably at at least five diffraction angles out of seven diffraction angles (2θ) of 15.3 to 15.5°, 25.7 to 25.9°, 29.6 to 29.8°, 30.84 to 31.04°, 30.95 to 31.15°, 31.90 to 32.10°, and 37.35 to 37.55° in X-ray diffraction using CuKα characteristic X-rays (wavelength of 1.54056 Å).

The blue light-emitting phosphor according to the embodiment has a composition different from those of conventional fluorescent bodies. The half-width of the emission spectrum of the blue light-emitting phosphor according to the embodiment is wider than that of a BAM phosphor (BaMgAl₁₀O₁₇:Eu²⁺) that has been widely commercialized as a blue phosphor. Use of the phosphor according to the embodiment enables a white light-emitting device with high color rendering properties to be obtained.

### [Method for Producing Blue Light-Emitting Phosphor]

The blue light-emitting phosphor according to the present embodiment can be produced by an arbitrary method. For example, the blue light-emitting phosphor according to the present embodiment can be produced by mixing and burning raw material powders containing each element.

A Sr-containing raw material can be selected from nitrides, silicides, carbides, carbonates, hydroxides, and oxides of Sr. A M-containing raw material can be selected from nitrides, silicides, carbides, carbonates, hydroxides, and oxides of M. An Al-containing raw material can be selected from nitrides, oxides, and carbides of Al, and a Si-containing raw material can be selected from nitrides, oxides, and carbides of Si. A Ce-containing raw material can be selected from chlorides, oxides, nitrides, and carbonates of Ce.

Nitrogen can be given from a nitride raw material or by burning in atmosphere containing nitrogen, and oxygen can be given from an oxide raw material or from a surface oxidation coating of a nitride raw material.

In order to produce the phosphor according to the present embodiment, for example, SrSi₂, CeCl₃, Si₃N₄, AlN, and Al₂O₃ as raw material powders are mixed in such preparation composition as to be composition of interest. Sr₃N₂, Sr₂N, SrN, SrC₂, or the like, or a mixture thereof may be used instead of SrSi₂. The raw materials can be mixed, for example, using a mortar in a glove box. The mixed powders are encased in a crucible and burned under predetermined conditions, to thereby obtain the phosphor according to the present embodiment. The material of the crucible is not particularly limited but can be selected from boron nitride, silicon nitride, silicon carbide, carbon, aluminum nitride, sialon, aluminum oxide, molybdenum, tungsten, and the like.

It is desirable to burn the mixed powders at a pressure that is not less than atmospheric pressure. The burning at the pressure that is not less than atmospheric pressure is advantageous in view of inhibiting silicon nitride from decomposing. For suppressing the decomposition of silicon nitride at high temperature, a pressure (absolute pressure) of 5 atmospheres or more is more preferable, and a burning temperature ranging from 1500 to 2000° C. is preferable. Such conditions allow a sintered body of interest to be obtained without causing trouble such as sublimation of a material or a product. When there are a plurality of burning steps, it is preferable to perform some or all of the burning steps under a pressurization condition, as mentioned below.

The burning atmosphere preferably has a low oxygen content in every burning step. This is because oxidation of raw materials such as AlN is avoided. Specifically, burning in nitrogen atmosphere, high-pressure nitrogen atmosphere, or deoxidation atmosphere is desired. The atmosphere may contain up to around 50 vol % of hydrogen molecules.

The burning time, which is not particularly limited, is, for example, 4 to 80 hours, preferably 6 to 60 hours.

The method for producing the phosphor according to the present embodiment can comprise two or more burning steps in which the burning atmosphere and the burning temperature are varied.

For example, burning can be performed under atmosphere containing hydrogen and nitrogen in the first burning step, and burning can be performed under atmosphere containing only nitrogen in the second burning step. In addition, variations in pressure and temperature can be made between the first burning step and the second burning step. Furthermore, burning can be performed twice or more on the same conditions without changing the burning conditions. For example, after the first primary burning step, the resulting sintered body can be crushed and re-burned on the same conditions.

After the burning, as needed, post-treatment such as cleaning is performed to obtain a phosphor according to an embodiment. For example, pure water, an acid, or the like can be used in the cleaning. Examples of the acid that can be used include inorganic acids such as sulfuric acid, nitric acid, hydrochloric acid, and hydrofluoric acid; organic acids such as formic acid, acetic acid, and oxalic acid; mixed acids thereof; and the like.

Before or after acid cleaning, post-annealing treatment may be performed as needed. The order of the post-annealing and the acid cleaning can be appropriately changed depending on an objective. The post-annealing treatment can be performed, for example, in reducing atmosphere containing nitrogen and hydrogen. Crystallinity and luminous efficiency are improved by such post-annealing treatment.

### [Light-Emitting Device]

A light-emitting device according to an embodiment comprises a combination of: a light-emitting element which is an excitation light source; and the blue light-emitting phosphor (B) which is excited by light irradiated from the light-emitting element, to emit fluorescence. In this case, the light-emitting device emits light in which light irradiated from the light-emitting element and light emitted from the blue light-emitting phosphor are synthesized.

It is necessary that the light-emitting element used in the light-emitting device, e.g., an LED element is an element emitting light that can excite a phosphor used.

From such a viewpoint, the light-emitting element that emits light having a wavelength of 250 to 430 nm, preferably 250 to 400 nm is selected in the fluorescence device in which the blue light-emitting phosphor is used as a phosphor.

In addition to the blue light-emitting phosphor (B) as a first phosphor, a phosphor as a second or a third phosphor that emits light in another wavelength region can be combined in a light-emitting device according to an embodiment. Examples of such fluorescent bodies include a phosphor emitting light having a peak in a wavelength range of 490 to 580 nm (green light-emitting phosphor (G)), a phosphor emitting light having a peak in a wavelength range of 500 to 600 nm (yellow light-emitting phosphor (Y)), a phosphor emitting light having a peak in a wavelength range of 600 to 660 nm (red light-emitting phosphor (R)), and the like. The phosphor other than the blue light-emitting phosphor may be excited by light irradiated from the light-emitting element or may be excited by light emitted from the blue light-emitting phosphor. The phosphors are used appropriately in combination depending on the color, color temperature, color rendering properties, and the like of light emitted from a light-emitting device of interest.

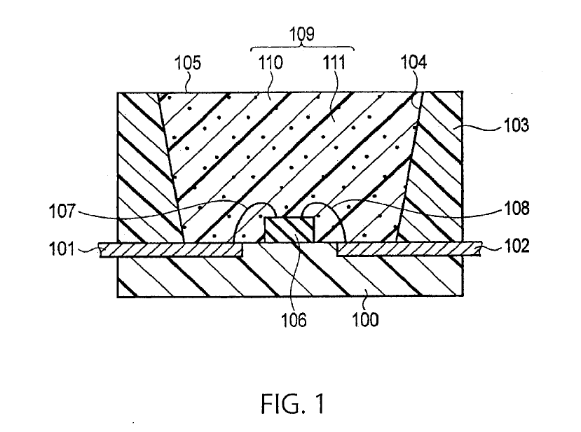

A light-emitting device according to an embodiment can be in the form of a conventionally known arbitrary light-emitting device. FIG. 1 illustrates the cross section of a light-emitting device according to an embodiment of the present invention.

A light-emitting device according to an embodiment of the present invention can be in the form of a conventionally known arbitrary light-emitting device. FIG. 1 illustrates the cross section of a light-emitting device according to an embodiment of the present invention.

In the light-emitting device illustrated in FIG. 1, a substrate 100 has: a lead 101 and a lead 102 that are obtained by forming lead frames; and a resin portion 103 that is formed integrally therewith. The resin portion 103 has a recess 105 of which the upper opening is wider than the bottom surface portion. A reflecting surface 104 is disposed on a side of the recess.

A light-emitting element 106 is mounted, with an Ag paste or the like, on the center of the generally circular bottom surface of the recess 105. Examples of the light-emitting element 106 that can be used include a light-emitting diode, a laser diode, and the like. The light-emitting element is selected from light-emitting elements emitting light having an appropriate wavelength depending on a combination of fluorescent bodies used. For example, a semiconductor light emitting element, such as a GaN-based semiconductor light emitting element, or the like can be used. The electrodes (not illustrated) of the light-emitting element 106 are connected, through bonding wires 107 and 108 comprising Au or the like, to the lead 101 and the lead 102, respectively. The arrangement of the leads 101 and 102 can be appropriately changed.

A fluorescent layer 109 can be formed by dispersing or settling a necessary phosphor 110 at a percentage of 5 to 70 mass %, for example, in a resin layer 111 comprising silicone resin. The phosphor can be used in combination of the blue light-emitting phosphor (B) according to the embodiment with another phosphor, e.g., a yellow luminescence phosphor (Y) or the like. For example, a light-emitting device emitting white light can be formed by combining the blue light-emitting phosphor (B) according to the present embodiment with an arbitrary yellow luminescence phosphor (Y) in a ratio of about 90:10. In the phosphor according to the embodiment, an oxynitride with high covalency is used as a host material. Therefore, in general, the phosphor according to the embodiment of the present invention is hydrophobic and has excellent compatibility with resins. Accordingly, scattering on the interface between the resin and the phosphor is markedly suppressed to improve light extraction efficiency.

As the light-emitting element 106, a flip-chip-type light-emitting element including an n-type electrode and a p-type electrode on the same surface can also be used. In such a case, problems caused by a wire, such as the disconnection and peeling of the wire, and the absorption of light into the wire, are solved to provide a semiconductor light-emitting device with high reliability and high luminance. The following structure in which an n-type substrate is used in the light-emitting element 106 can also be made. Specifically, an n-type electrode is formed on the back surface of the n-type substrate, and a p-type electrode is formed on the top surface of the semiconductor layer in the substrate, so that the n-type electrode or the p-type electrode is mounted on a lead. The p-type electrode or the n-type electrode can be connected to the other lead through a wire. The size of the light-emitting element 106, and the dimension and shape of the recess 105 can be appropriately changed.

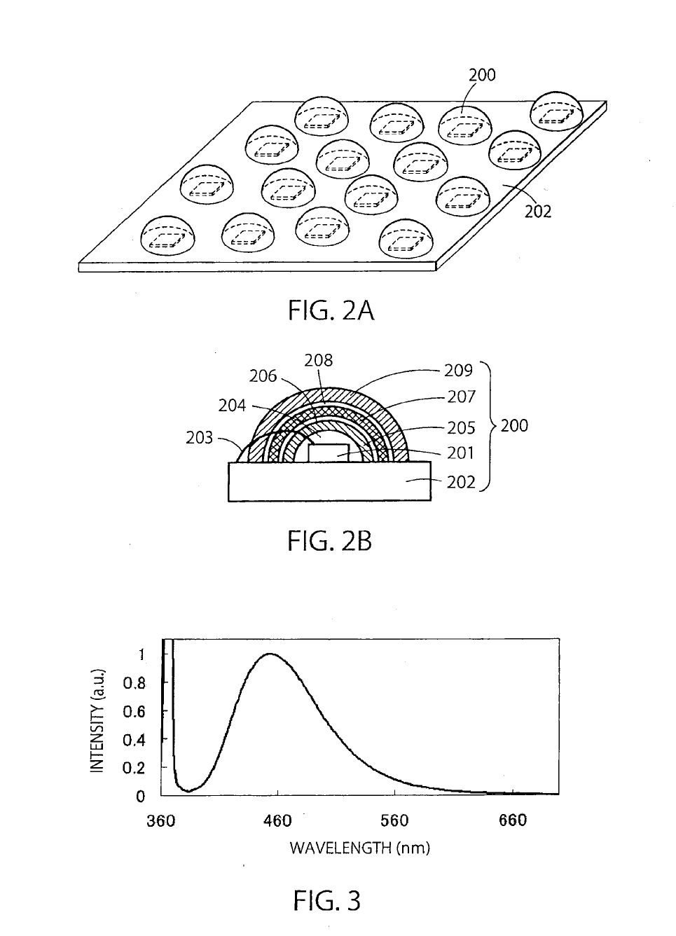

A light-emitting device or a light-emitting device module in another form can be produced using the phosphor according to the embodiment. FIG. 2 is a conceptual diagram of such a light-emitting device and a light-emitting device module. In the light-emitting device module (FIG. 2A), plural bullet-type light-emitting devices 200 are placed on a surface of a heat radiation substrate 202. In addition, the bullet-type light-emitting device comprises a structure illustrated in FIG. 2B. The light-emitting device module is specifically produced as described below. First, 16 light-emitting diodes 201 with an emission peak wavelength of 390 nm are prepared. The light-emitting diodes are placed on the heat radiation substrate 202 so that the spacings between the centers of the light-emitting diodes are 6 mm. The light-emitting diodes are joined using solder and further connected to electrodes through gold wires 203. The light-emitting device module can be produced by: forming a transparent resin layer 204 in a dome shape on each light-emitting diode; forming a transparent resin layer 205 mixed with a red light-emitting phosphor having a peak wavelength of 628 to 653 nm in a layer shape on the transparent resin layer 204; further sequentially applying, on the transparent resin layer 205, a transparent resin layer 206 as well as a transparent resin layer 207 and a transparent resin 208, mixed with a yellow phosphor having a peak wavelength of 548 nm, in layer shapes; and further sequentially layering and applying, on the transparent resin 208, a transparent resin 209 mixed with the blue phosphor according to the embodiment. Each light-emitting device can be allowed to have a circular shape viewed from above the top surface and to have a diameter of around 3.0 mm.

The light-emitting device according to the embodiment of the present invention is not limited to such package-cup-type light-emitting devices as illustrated in FIG. 1 or to such bullet-type light-emitting devices as illustrated in FIG. 2 but can be appropriately changed. Specifically, the phosphor of the embodiment can also be applied to a bullet-type light-emitting device or a surface-mount-type light-emitting device, to obtain a similar effect.

The fluorescence light-emitting layer of the light-emitting device according to the present embodiment may contain a phosphor (Y) that emits yellow light by excitation with blue light, a phosphor (G) that emits green light by excitation with blue light, and a phosphor (R) that emits red light by excitation with blue light, as well as the blue light-emitting phosphor according to the present embodiment. In this case, a white light-emitting device superior in color rendering properties is obtained. Fluorescent bodies with different luminescent colors can also be incorporated into different fluorescent light-emitting layers, to make a layered structure including a fluorescent light-emitting layer containing a blue light-emitting phosphor, a fluorescent light-emitting layer containing a green light-emitting phosphor, and a fluorescent light-emitting layer containing a red light-emitting phosphor.

The present embodiment will be described in more detail below with reference to various examples. However, the present invention is not limited only to the examples.

### EXAMPLES 1 TO 8

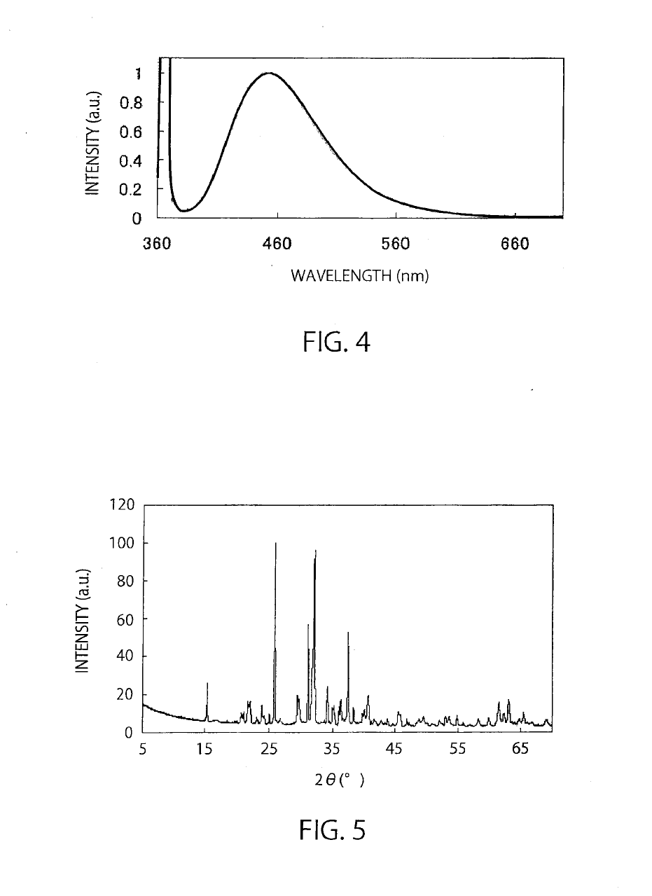

SrSi₂, CeCl₃, Si₃N₄, AlN, and Al₂O₃ were prepared as starting materials. These raw materials were weighed in corresponding amounts listed in Table 1 so as to correspond to the designed composition of each example, and were mixed to yield a raw material mixture. Each raw material mixture, which was filled into a BN crucible, was burned. For example, in Example 1, first, heating was performed under atmosphere having a mixing ratio (molar ratio) H₂:N₂ of 1:1 at 1 atmospheric pressure and 1500° C. for 12 hours, and the resulting burned product was crushed. This procedure was repeated three times, followed by performing heating under nitrogen atmosphere at a pressure of 7.5 atmospheres and 1850° C. for 10 hours and by crushing the resulting burned product, to yield a phosphor of interest. Every resulting phosphor emitted blue light when irradiated with excitation light of 365 nm. FIG. 3 and FIG. 4 show the emission spectra of the phosphors of Examples 2 and 3. In FIG. 3 and FIG. 4, the peaks at wavelengths of around 365 nm are caused by the reflected light of excitation light.

TABLE 1

| | | Amoung [g] of each reagent | | | | | |
|---|---|---|---|---|---|---|---|
| | | | | | | | Total |
| | Designed composition | SrSi₂ | CeCl₃ | Si₃N₄ | Al₂O₃ | AlN | amount |
| Example 1 | (Sr_{0.97}Ce_{0.03})₃Si₁₃Al₃O₂N₂₁ | 4.184 | 0.222 | 3.358 | 0.510 | 0.820 | 9.094 |
| Example 2 | (Sr_{0.955}Ce_{0.045})₃Si₁₃Al₃O₂N₂₁ | 4.120 | 0.333 | 3.400 | 0.510 | 0.820 | 9.182 |
| Example 3 | (Sr_{0.97}Ce_{0.03})₃Si_{13.5}Al_{2.5}O_{1.5}N_{21.5} | 3.347 | 0.177 | 2.874 | 0.272 | 0.601 | 7.272 |
| Example 4 | (Sr_{0.955}Ce_{0.045})₃Si_{13.5}Al_{2.5}O_{1.5}N_{21.5} | 3.296 | 0.266 | 2.907 | 0.272 | 0.601 | 7.342 |
| Example 5 | (Sr_{0.97}Ce_{0.03})₃Si_{14.0}Al_{2.0}O_{1.0}N₂₂ | 3.347 | 0.177 | 3.061 | 0.136 | 0.547 | 7.268 |
| Example 6 | (Sr_{0.955}Ce_{0.045})₃Si_{14.0}Al_{2.0}O_{1.0}N₂₂ | 3.296 | 0.266 | 3.094 | 0.136 | 0.547 | 7.339 |
| Example 7 | (Sr_{0.97}Ce_{0.03})₃Si_{14.5}Al_{1.5}O_{0.5}N_{22.5} | 4.184 | 0.222 | 4.060 | 0.000 | 0.615 | 9.081 |
| Example 8 | (Sr_{0.955}Ce_{0.045})₃Si_{14.5}Al_{1.5}O_{0.5}N_{22.5} | 4.120 | 0.333 | 4.102 | 0.000 | 0.615 | 9.169 |

The emission spectrum of each phosphor was measured in the case of excitation with excitation light of 365 nm or 405 nm, and the emission peak wavelength of each emission spectrum and the half-width, corresponding to the emission peak wavelength, of the emission spectrum were measured. The obtained results are as listed in Table 2.

TABLE 2

| | 365 nm Excitation | | 405 nm Excitation | |
|---|---|---|---|---|
| | Emission | | Emission | |
| | peak | Emission | peak | Emission |
| | wavelength | half-width | wavelength | half-width |
| | [nm] | [nm] | [nm] | [nm] |
| Example 1 | 450 | 96 | 475 | 112 |
| Example 2 | 454 | 85 | 468 | 90 |
| Example 3 | 453 | 86 | 465 | 92 |
| Example 4 | 455 | 87 | 464 | 93 |
| Example 5 | 459 | 92 | 468 | 98 |
| Example 6 | 460 | 93 | 472 | 99 |
| Example 7 | 467 | 101 | 477 | 108 |
| Example 8 | 468 | 103 | 477 | 110 |

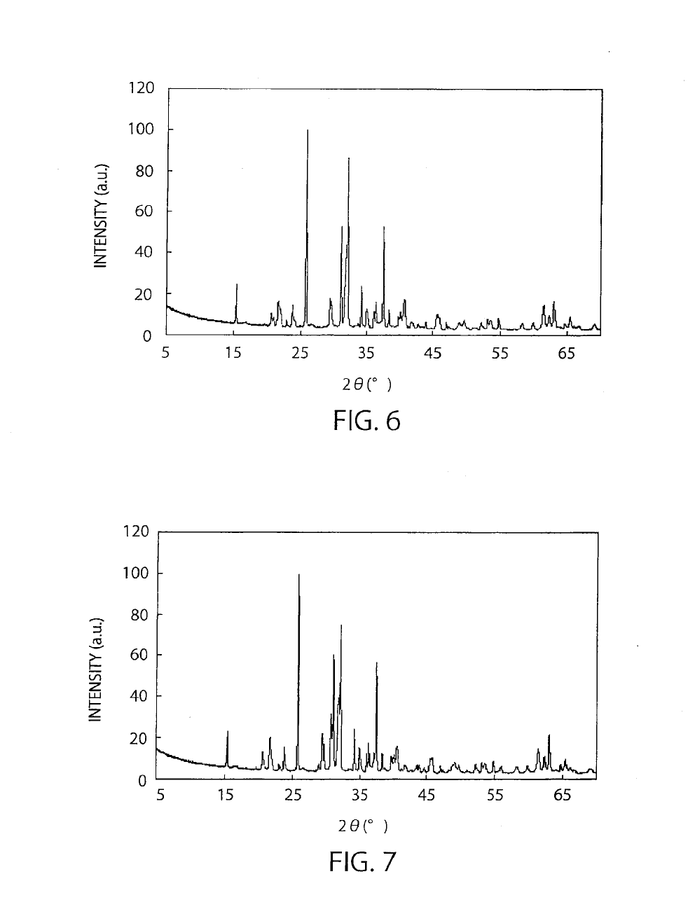

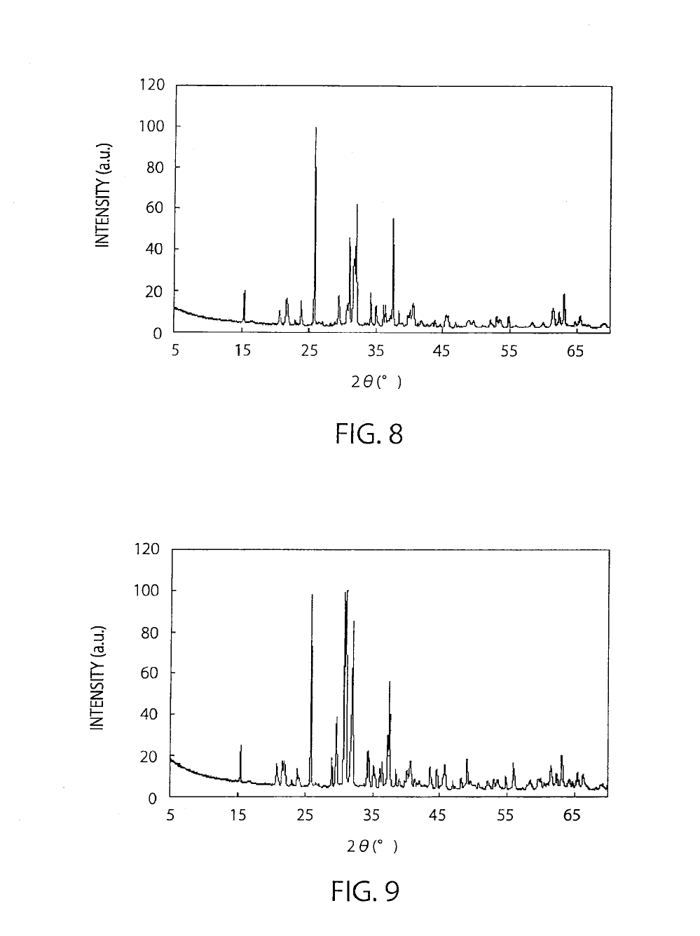

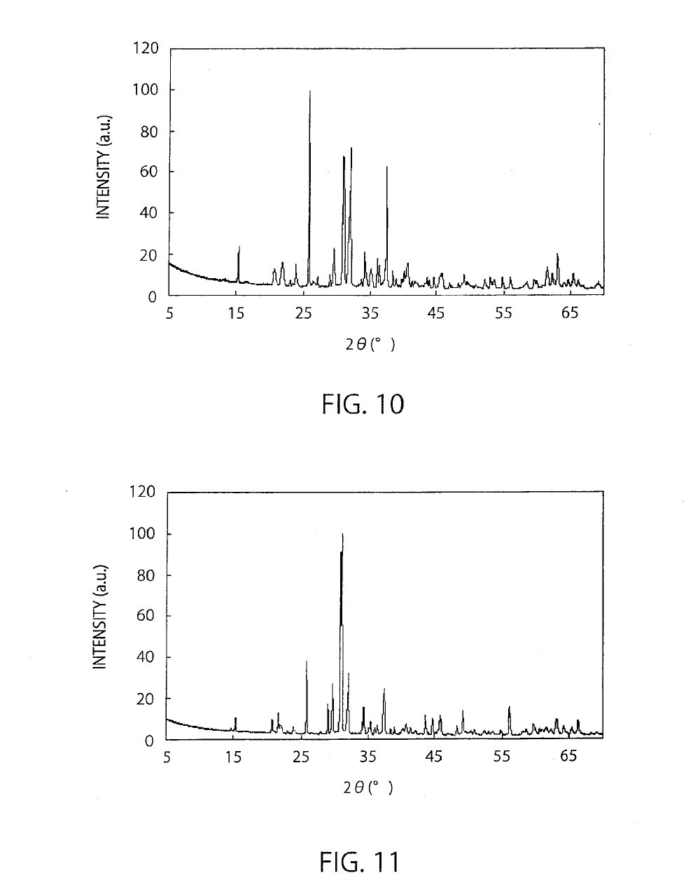

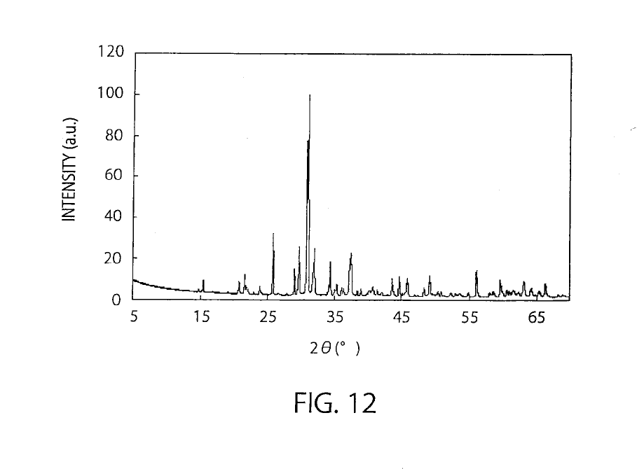

The XRD profiles of the resulting fluorescent bodies are as shown in FIGS. 5 to 12. The fluorescent bodies according to Examples 1 to 8 contained one component simultaneously exhibiting diffraction peaks at at least five diffraction angles out of seven diffraction angles (2θ) of 15.3 to 15.5°, 25.7 to 25.9°, 29.6 to 29.8°, 30.84 to 31.04°, 30.95 to 31.15°, 31.90 to 32.10°, and 37.35 to 37.55° in X-ray diffraction using CuKα characteristic X-rays (wavelength of 1.54056 Å).

M, Si, Al, and Ce can be measured by, for example, inductively coupled plasma atomic emission spectroscopy (which may also be referred to as ICP emission spectroscopy). Specifically, a sample of an oxynitride phosphor is measured in a platinum crucible and is decomposed by alkali fusion, and an internal standard element Y is added to the resultant to prepare a measurement solution, which is measured by ICP emission spectroscopy. As a measuring apparatus, for example, SPS-3520 UV 4000 Type ICP Emission Spectrophotometer (trade name, manufactured by SII NanoTechnology Inc.) can be used for M, Si, and RE.

O and N can be measured by, for example, an inert gas fusion method. Specifically, a sample of an oxynitride phosphor is heated and fused in a graphite crucible, O contained in the sample is made, by an inert gas transportation method, into CO, which is further oxidized to CO₂, the content of oxygen is then measured by an infrared absorbing method, CO₂ is further removed, and the content of N is then measured by thermal conductimetry. As a measuring apparatus, for example, TC-600 Type Oxygen/Nitrogen/Hydrogen Elemental Analyzer (trade name, manufactured by LECO Corporation (USA)) can be used.

The obtained composition analysis results are as listed in Table 3. The compositions listed in the table are standardized to meet Si+Al=16.

TABLE 3

| | Sr | Ce | Si | Al | O | N |
|---|---|---|---|---|---|---|
| Example 1 | 2.92 | 0.11 | 12.82 | 3.18 | 1.77 | 21.43 |
| Example 2 | 2.84 | 0.14 | 12.82 | 3.18 | 1.87 | 21.65 |
| Example 3 | 2.86 | 0.11 | 13.36 | 2.64 | 1.80 | 20.94 |
| Example 4 | 2.74 | 0.14 | 13.30 | 2.70 | 1.82 | 21.54 |
| Example 5 | 2.80 | 0.09 | 14.00 | 2.00 | 1.33 | 21.12 |
| Example 6 | 2.48 | 0.16 | 13.89 | 2.11 | 1.32 | 21.49 |
| Example 7 | 2.79 | 0.09 | 14.48 | 1.52 | 1.06 | 20.86 |
| Example 8 | 2.70 | 0.14 | 14.53 | 1.47 | 1.06 | 20.87 |

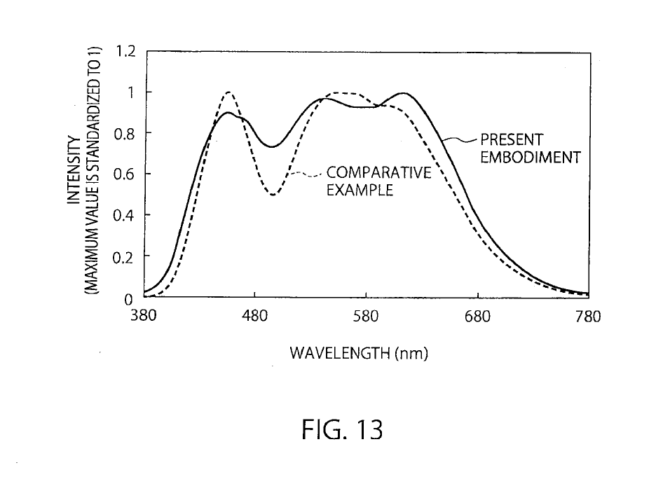

In addition, a light-emitting device for emitting white light, in which the phosphor of Example 2 and a yellow light-emitting phosphor were combined, was produced. For comparison, a light-emitting device for comparison was produced using a BAM phosphor (BaMgAl₁₀O₁₇:Eu²⁺) commonly used as a blue light-emitting phosphor. The emission spectra of the light-emitting devices are as shown in FIG. 13. It was confirmed that the light-emitting device in which the phosphor of Example 2 was used emitted much light at around 500 nm and exhibited high color rendering properties.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fail within the scope and spirit of the invention.

1. A phosphor exhibiting a luminescence peak in a wavelength range of 430 to 490 nm when excited with light having a luminescence peak within a wavelength range of 250 to 430 nm,
wherein the phosphor represented by the following formula (1):
((SrₚM₁₋ₚ)₁₋ₓCeₓ)_{3-y}Si_{13-z}Al_{3+z}O₂₊ᵤN_{21-w} (1)
(wherein M is at least one of alkaline earth metals; and
0≦p≦1,
0<x≦1,
−0.1≦y≦0.6,
−3.0≦z≦0.4,
−1.5<u≦−0.3, and
−3.0<u−w≦1.0
are satisfied).

2. The phosphor according to claim 1, wherein the M is an element selected from the group consisting of Ba, Ca, and Mg.

3. The phosphor according to claim 1, wherein a difference between a lattice constant of a structure possessed by a crystal of Sr₃Si₁₃Al₃O₂N₂₁ and a lattice constant of a crystal of the phosphor is within ±15%.

4. The phosphor according to claim 1, wherein differences between chemical bond lengths of Sr—N and Sr—O in Sr₃Si₁₃Al₃O₂N₂₁ and chemical bond lengths of M-N and M-O in a crystal of the phosphor are within ±15%.

5. The phosphor according to claim 1, wherein the phosphor comprises at least five peaks at diffraction angles (2θ) of 15.3 to 15.5°, 25.7 to 25.9°, 29.6 to 29.8°, 30.84 to 31.04°, 30.95 to 31.15°, 31.90 to 32.10°, and 37.35 to 37.55° in X-ray diffraction by a Bragg-Brendano method using Cu-Kα line.

6. The phosphor according to claim 1, wherein the phosphor is a Sr₃Si₁₃Al₃O₂N₂₁-based crystal.

7. A light-emitting device comprising:
a light-emitting element which emits light having a luminescence peak in a wavelength range of 250 to 430 nm;
the first phosphor according to claim 1; and
a second phosphor which emits light having a peak in a wavelength range of 500 to 600 nm when excited with irradiation light from the light-emitting element.

8. A light-emitting device comprising:
a light-emitting element which emits light having a luminescence peak in a wavelength range of 250 to 430 nm;
the first phosphor according to claim 1;
a second phosphor which emits light having a peak in a wavelength range of 500 to 600 nm when excited with light from the light-emitting element; and
a third phosphor which emits light having a peak in a wavelength range of 600 to 660 nm when excited with light from the light-emitting element.
